(19) United States
(12) Patent Application Publication
(10) Pub. No.: US 2025/0296315 A1
(43) Pub. Date: Sep. 25, 2025

(54) DELAMINATION OF PHOTOVOLTAIC MODULE

(71) Applicant: SOLARCYCLE, Inc., Mesa, AZ (US)

(72) Inventors: Pablo RIBEIRO DIAS, Mesa, AZ (US); Gustavo Da Rosa Cunha, Mesa, AZ (US); Lucas Margarezzi Schmidt, Mesa, AZ (US); Marcelo Pilotto Cenci, Mesa, AZ (US)

(21) Appl. No.: 19/085,850

(22) Filed: Mar. 20, 2025

Related U.S. Application Data
(60) Provisional application No. 63/568,336, filed on Mar. 21, 2024.

(51) Int. Cl. B32B 43/00; H10F 19/80

(52) U.S. Cl. CPC B32B 43/006; H10F 19/804; B32B 2457/12

(57) ABSTRACT

Embodiments may perform delamination of a photovoltaic module through the application of radiation. Radiation of one or more specific types—e.g., microwave (MW); Infrared (IR); others—may be applied to one or more faces of the PV module. By targeting polymer(s) of a laminate, radiation emitters (MW; IR; and/or other) may be energy efficient, avoiding the need to heat up the full large thermal mass of an entire laminate. By focusing upon absorption of the radiation by polymer(s), embodiments may allow for the applied radiation to be better used during the delamination process.

### CROSS-REFERENCE TO RELATED APPLICATION

The instant nonprovisional patent application claims priority to U.S. Provisional Patent Application No. 63/568,336 filed Mar. 21, 2024 and incorporated by reference herein for all purposes.

### BACKGROUND

Delamination is a step in the recycling process of PV modules. Delamination can be expensive and/or complicated technically to perform.

The PV module may be made of different layers put together in a sandwich-like structure. These layers can be a substrate (backsheet-which may be glass in the case of bifacial modules, or a polymer in the case of monofacial), encapsulant (e.g., a polymer such as ethylene vinyl acetate-EVA, or polyolefin elastomer-POE), solar cell or thin-film layer, encapsulant, glass. Some panels only have one layer of encapsulant, such as CdTe panels. This structure is referred to herein as a laminate. Delamination refers to separating one or more of such layers. The laminate may be surrounded by an aluminum frame or by a steel structure.

PV modules such as CdTe, CIS, CIGS and a-Si may have a similar yet different structure (e.g. no frame). But, such modules may also be put together in a sandwich-like structure referred to here as a laminate.

### SUMMARY

Embodiments may perform delamination of a photovoltaic module through the application of radiation. Radiation of one or more specific types—e.g., microwave (MW); Infrared (IR); others—may be applied to one or more faces of the PV module. By targeting polymer(s) of a laminate, radiation emitters (MW; IR; and/or other) may be energy efficient, avoiding the need to heat up the full large thermal mass of an entire laminate. By focusing upon absorption of the radiation by polymer(s), embodiments may allow for the applied radiation to be better used during the delamination process.

### BRIEF DESCRIPTION OF THE DRAWINGS

FIG. 1 shows cross-sectional views of the application of radiation to a backside of a used solar module, according to one embodiment.

FIG. 2 shows cross-sectional views of the application of radiation to a backside of a used solar module, according to an embodiment.

FIG. 3 shows cross-sectional views of the application of radiation to a front side of a used solar module, according to an embodiment.

FIG. 4 shows an apparatus according to an embodiment, wherein a silicon/glass mixture is transported on a vibrating table until the mixture encounters notches or barriers.

FIG. 5 shows an apparatus according to an alternative embodiment, built with several notches in the table.

FIG. 6 shows an apparatus according to an alternative embodiment, wherein a silicon/glass mixture is transported on a vibrating table until the mixture encounters a ramp.

FIG. 7 shows module delamination to generate glass/silicon/ribbons mixture.

FIG. 8A shows a visual aspect of a sample before thermal treatment with microwave radiation.

FIG. 8B shows a visual aspect of a sample after microwave thermal treatment.

FIG. 9 shows a simplified view of an embodiment with modules sandwiched with two rock wool layers.

FIG. 10 shows a simplified flowchart for an embodiment of a recycling method.

FIGS. 11-14 show results of electrostatic separation.

FIG. 15A shows a simplified top view of an apparatus for separation according to an embodiment, comprising a succession of groove features.

FIG. 15B shows a simplified side view of the apparatus of FIG. 15A.

FIG. 15C is a simplified view showing a trajectory of thin material.

FIG. 15D is a simplified view showing a trajectory of the thick material.

FIG. 16 is a simplified flow diagram of a method of delamination according to an embodiment, with the emitter applying radiation having an energy less than a furnace.

FIG. 17 is a simplified flow diagram of an alternative embodiment of a method of delamination where radiation from an emitter is then applied to the opposite side.

FIG. 18 shows a simplified flow diagram of an alternative embodiment of a method of delamination where radiation is continued to be applied from the original side.

FIG. 19 shows a simplified view of an embodiment of an apparatus for pyrolysis.

FIG. 20 shows a particular embodiment where the radiation emitter (and possible reflective surface) are present with the laminate within a sealed chamber.

FIG. 21 shows a particular embodiment where the radiation emitter/reflective surface are external to the laminate within a sealed chamber.

### DESCRIPTION

Delaminating a PV module according to embodiments separates the layers of a laminate structure into one of more layers. Different layers are made of different materials, and in certain embodiments it may be desirable to perform delamination multiple times in succession to remove layers.

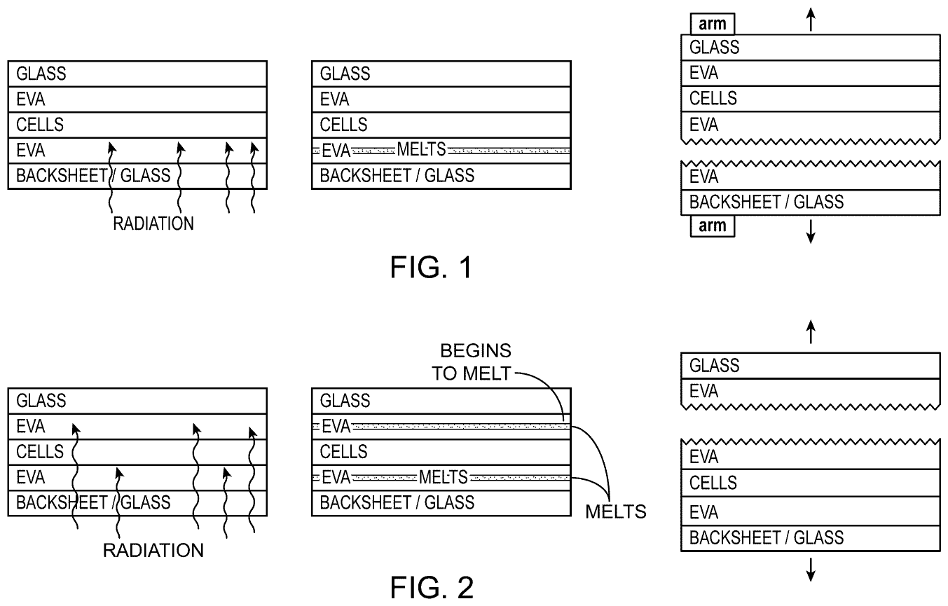

In one specific embodiment shown in FIG. 1, delamination begins by gripping opposite exterior faces of the laminate. This can be achieved by adhering such faces to outer arm-like components. Adhesion can take place by chemically bonding the face and the arm, and/or by mechanically gripping the face with a mechanism such as a suction cup, and/or by friction using increased surface area.

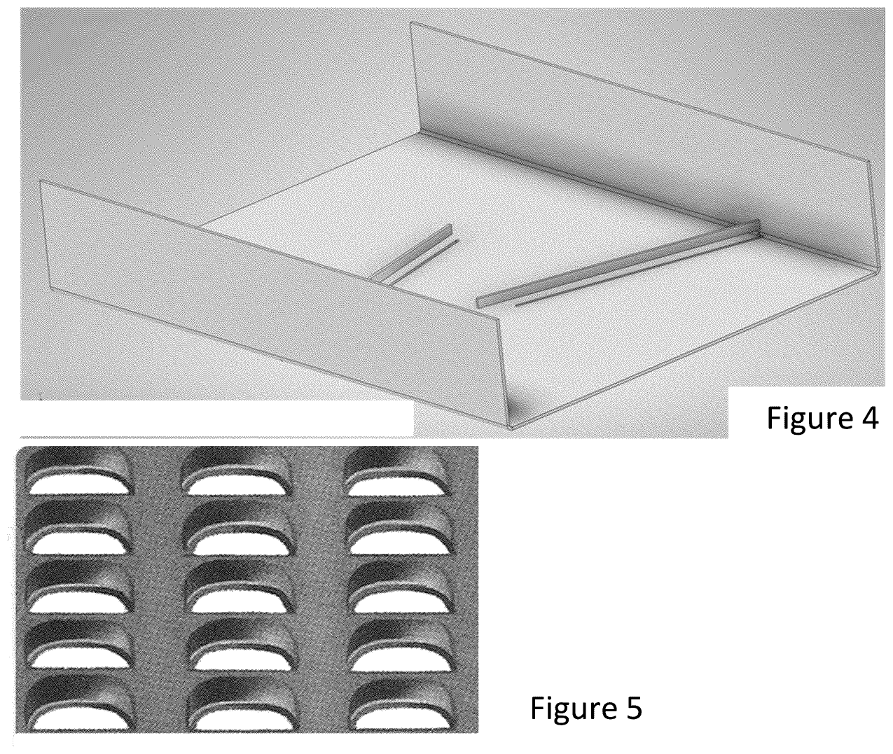

Embodiments using suction cups can adhere to rough surfaces such as broken glass. Suction cups may be available in multiple sizes, including small sizes of 10 mm diameter or smaller. This can allow for several cups to be deployed in a single solar panel. FIG. 3 shows a simplified embodiment utilizing suction cups. For example, in particular embodiments in which the glass is broken, eight thousand suction cups could be used to promote interaction of sections of the glass grains with at least one suction cup.

A next step is to use radiation to heat the polymer encapsulant layer holding the different layers around it together. Embodiments may want to heat up polymer encapsulant to the point at which it melts or softens (e.g., its viscosity changes) in order to lower its adhesion to the surrounding layers. Certain embodiments may heat up the encapsulant to the point that it degrades, becoming a fluid and leaving the laminate.

This effect can be achieved by emitting radiation towards the main area of the panel. In particular embodiments, radiation with wavelengths of 2300, 1750, 1300, and/or 1200 nm represents the peak absorption for the EVA layer. However, due to the other materials present in the PV structure, stronger absorption of the EVA may be presented when the light wavelength is shorter than 380 nm or longer than 2200 nm. Wavelengths of 1064 and 2100 nm may be particularly suited for this purpose.

Various electromagnetic wavelengths may work to heat up the polymer (such as EVA). Examples can include infrared, microwave, visible, and others, which may be applied globally (e.g., using a furnace) and/or locally (using a targeted laser). Optimization can lie in finding the wavelengths that target the polymer more than the other materials.

The order of actions performed in delamination processes according to embodiments, can be varied. For example, the method can be inversed-, i.e., the radiation can be introduced first and the gripping of the opposite exterior faces later.

It is noted that FIGS. 1-3 illustrate the application radiation in a unidirectional manner from the emitter. This enhances the targeted delivery of radiation to desired polymer within the module.

For example, a monofacial module may include a backsheet comprising (the same or a different) polymer than the polymer encapsulant. Heating up that backsheet through the application of multidirectional radiation (e.g., in a furnace) can incur the unwanted side effect of liberating chemicals from the backsheet due to the presence of halogens.

However, by having the radiation applied in a unidirectional manner (e.g., from an emitter) the polymer encapsulant can be heated without also substantially heating the backsheet, thereby avoiding the formation of unwanted chemicals.

Embodiments may effectively separate different layers of the PV panel without damaging the layers. Damage may occur in the polymer (e.g., EVA) which may be torn into two (2) fractions: one adhered to the “top” (light facing) layers and one adhered to the “bottom” layers.

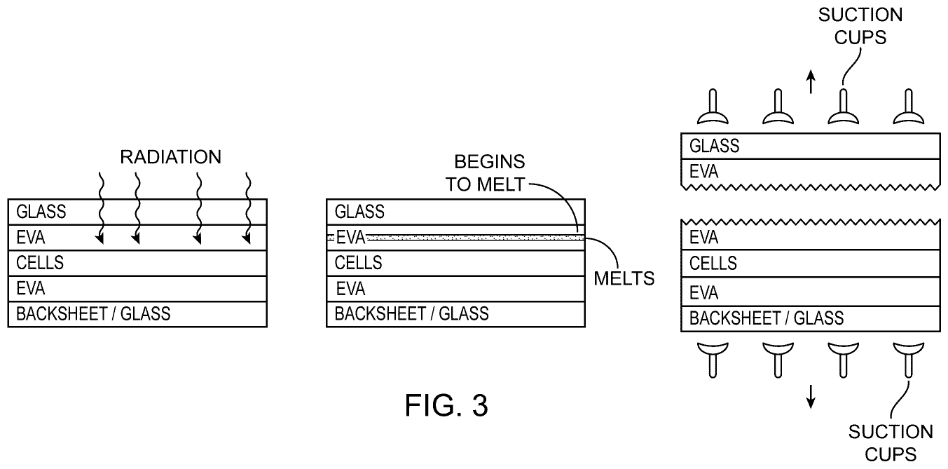

Embodiments of this process can be used in the polymer/EVA layer between the glass surface (superstrate) and the rest of the layers, as well as in the polymer/EVA layer between the substrate (backsheet or bottom glass surface—in the case of a bifacial module) and the rest of the layers. This is shown in the simplified view of the particular embodiment of FIG. 2, where radiation is applied from the backside. In other embodiments, however, radiation could also be applied from the frontside (alone or in combination with radiation from the backside).

In some embodiments, radiation may be applied to the side of the back sheet. Specific radiation types (not limited to wavelengths) may be more absorbed by encapsulant than back sheet layers (which in some embodiments may both comprise polymeric materials.

Certain embodiments relate to recycling of materials from bifacial (e.g., c-si) photovoltaic panels using thermal and/or mechanical processes. A controlled thermal process may be used to delaminate the module. Output materials are treated to recover metals of interest, utilizing one or more of:
electrostatic separation,
eddy current, and/or
thickness separation table.

Mechanical methods and apparatuses that recycle silicon from photovoltaic modules may separate the silicon wafer based on the difference of the thickness of the materials. More specifically, a thickness of the silicon wafer may range from about 150 to 300 micrometers. This may be thinner in comparison to the glass (about 3-4 mm for monofacial modules; about 2-2.4 mm for bifacial modules).

Some embodiments may use a thickness separation apparatus as part of a mechanical process. In one embodiment, an apparatus uses a vibrating rail to transport the material to be separated. The material passes through a system that separates the silicon wafer (or other thin material) and the glass (or other thicker material) in separated compartments. The system may comprise a table designed to have devices positioned at different angles and positions through which only the thin particles can pass while the thicker ones do not. Examples of apparatus embodiments are described as follows.

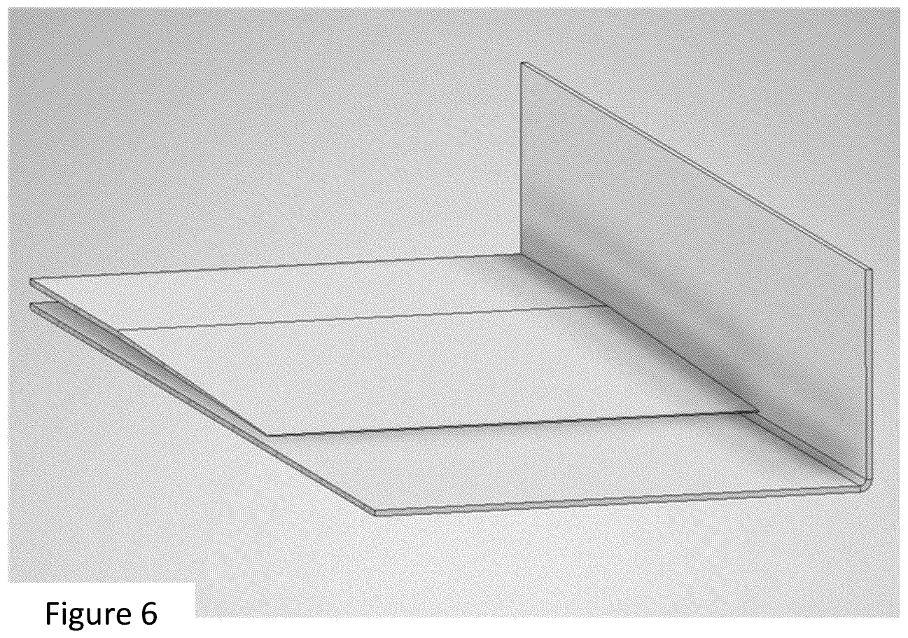

For the apparatus in the embodiment of FIG. 4, a silicon/glass mixture is transported on a vibrating table until the mixture encounters notches or barriers. The notches/barriers have a defined opening (higher than about 150 micrometers but lower than about 2 mm).

The silicon wafer can pass through the notches/barriers and falls into another compartment while the thicker materials are not collected and keeps vibrating until reaching another barrier. This process occurs in sequence (as many sequences as needed), and the glass fraction is collected at the end of the table.

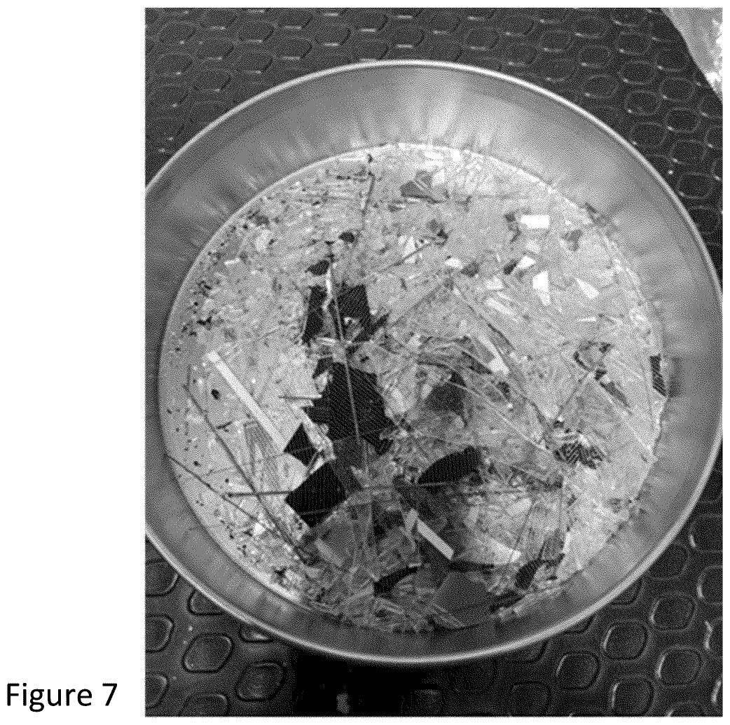

The design of FIG. 4 can be built with several notches in the table (in a manner analogous to a kind of grater). This is shown in FIG. 5.

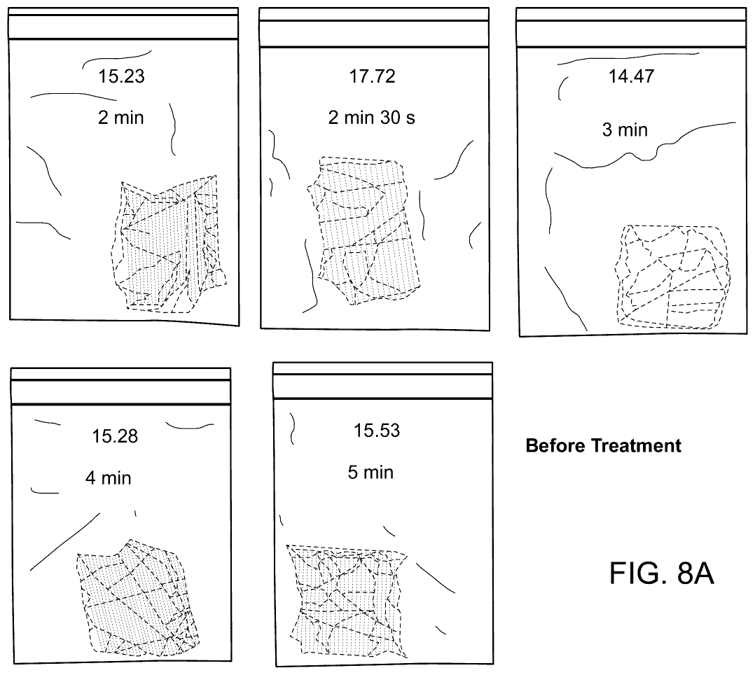

For the particular embodiment of apparatus shown in FIG. 6, a silicon/glass mixture is transported on a vibrating table until the mixture encounters a ramp. The ramp is positioned in a way that has a defined distance with the table (higher than about 150 micrometers but lower than about 2 mm).

The silicon wafer can pass through the ramp opening and keeps vibrating until it is collected in the end of the vibrating table. The thicker materials cannot pass through the opening and are transported over the ramp. A device that pulls the glass over the ramp may be employed.

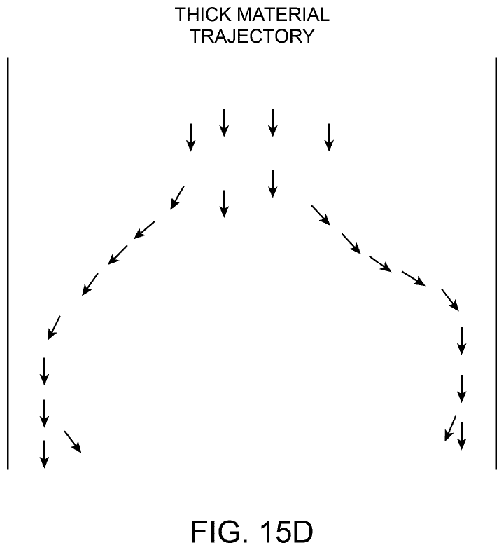

Another embodiment of an apparatus that may be used for separation based upon thickness, is shown in FIGS. 15A-D. In particular, the apparatus comprises a succession of groove features arranged as shown.

FIG. 15A shows a simplified top view of the apparatus, and FIG. 15B shows a simplified side view.

During operation, thin material would fall into the grooves. Thick material would slide sideways owing to the influence of one or more of:
the geometry of the board;
gravity;
vibration.

FIG. 15C is a simplified view showing the trajectory of thin material. FIG. 15D is a simplified view showing the trajectory of the thick material.

Embodiments may perform recycling of c-Si bifacial modules using thermal and mechanical processes. For a recycling method, a first step may be thermal delamination of the solar module. Two specific thermal processes were tested under different conditions.

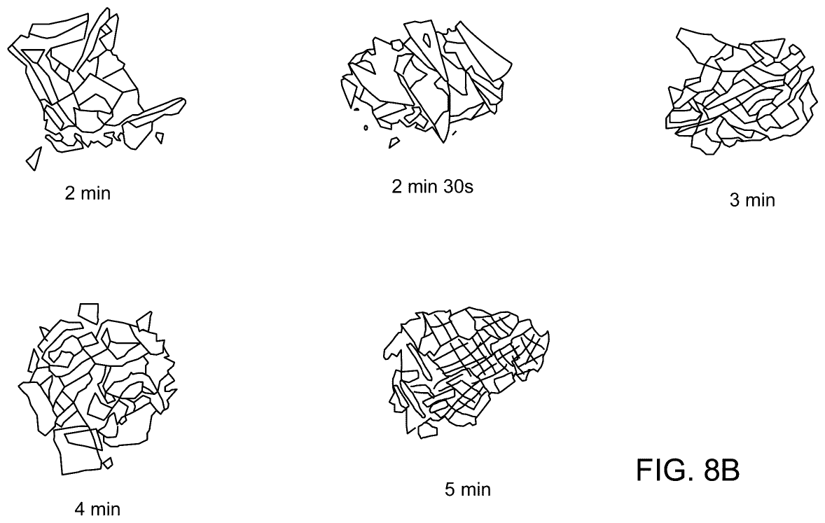

The first thermal process was carried out at a heating rate of 10° C./min from ambient to 550° C. and remained for 3 hours. EVA/POE encapsulant polymers can be removed with thermal processes at 500° C. The output materials from the thermal process #1 are shown in FIG. 7.

It is noted that particular embodiments are not limited to specific conditions. For example, alternative embodiments could perform delamination under conditions of about 650 degrees C. for a period of 30 minutes. Particular embodiments could involve the application of radiation under conditions that perform delamination in about 1 min or less per module.

As observed in FIG. 7, the solar modules are successfully delaminated, generating a glass, silicon, and ribbons mixture. The thermal process can be carried out under different conditions (temperature, time and atmosphere).

If the process is carried out in the presence of oxygen (i.e., normal ambient conditions), the encapsulant may ignite. Lowering the amount of oxygen ambient may avoid this outcome. Performing the process in the absence of oxygen may involve pyrolysis, which can (but need not be) employed. Embodiments that decrease in the amount of oxygen may assist with avoiding combustion.

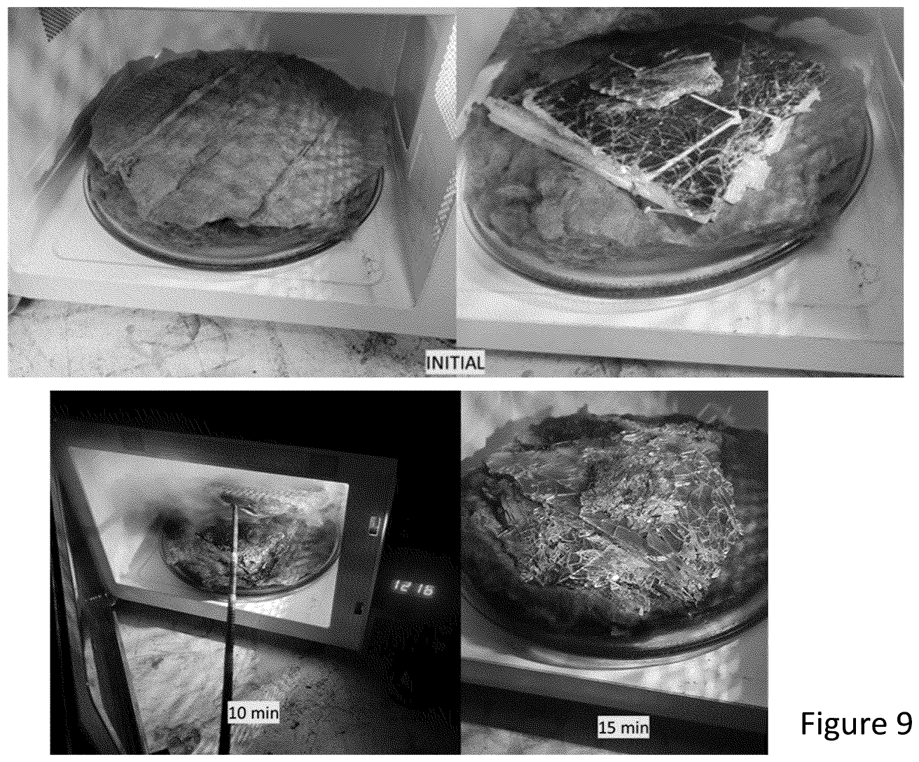

A second thermal process was studied by heating using a microwave. The trials were performed with maximum power (1600 W) under different times. The mass losses and the physical aspect of the samples are presented in Table 1 below and FIGS. 8A-B, which respectively show visual aspects of the samples before and after the thermal treatment with microwave.

TABLE 1
Mass evaluation for different times in the microwave.

| | Before | After | |
|---|---|---|---|
| Condition | Treatment (g) | Treatment (g) | Mass Losses (wt %) |
| 2 min | 15.93 | 15.13 | 5.02 |
| 2 min 30 s | 17.72 | 16.03 | 9.54 |
| 3 min | 14.47 | 12.52 | 13.48 |
| 4 min | 15.28 | 13.72 | 10.21 |
| 5 min | 15.53 | 14.03 | 9.66 |

Results show that it is possible to delaminate the bifacial modules using microwaves. The thermal treatment after 2 min did not completely delaminate the sample. The treatment after 2 min 30 seconds can delaminate the module but the burning is not complete as the color of the samples turned dark. The treatment of 4 minutes generated a clean and translucent glass.

A third test in the conventional microwave was performed to scale up the process and verify the consumption of energy. In this third test, 860.65 grams of a frameless bifacial solar panel was heated in the microwave for 15 minutes with two deodorization cycles totalizing 17 minutes.

The consumption of energy was 0.3-0.4 kWh and the final material presented 789.56 grams which represents 10.44% of losses. Considering the price of 13 cents per kWh, the cost to delaminate a frameless bifacial panel can vary from 1.44 to 1.92 $. It may be desirable for particular embodiments to reduce a cost to delaminate to $1 US dollar/module.

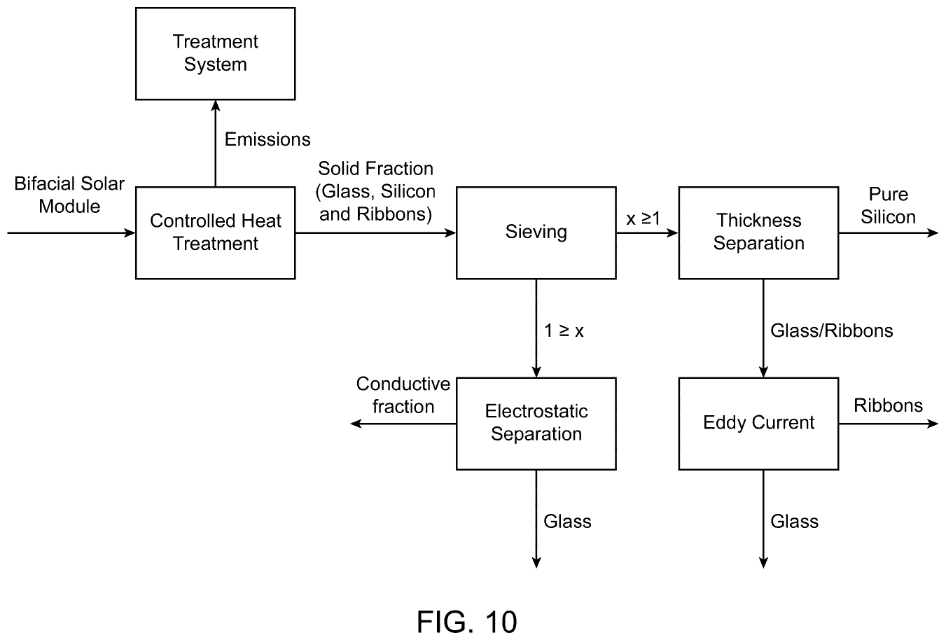

In this embodiment, the system was built with the modules sandwiched with two rock wool layers. The goal of using rock wool is to protect the microwave and guarantee manageability of the sample. The rock wool was previously dried. The system is shown in FIG. 9.

After 15 minutes the burn was complete (no dark aspect in the glass) and the module was completely delaminated.

The materials exhibit Particle Size Distribution (PSD). Two replicates of particle size distribution are shown in Table 2:

TABLE 2
PSD data for the output material of the thermal process #1.

| | Retained Materials | Retained Materials |
|---|---|---|
| Sieve Size (mm) | #1 (wt %) | #2 (wt %) |
| ≥9.5 | 6.99 | 46.11 |
| 9.5 ≥ x ≥ 4.75 | 32.95 | 26.42 |
| 4.75 ≥ x ≥ 2 | 53.57 | 21.65 |
| 2 ≥ x ≥ 1 | 1.65 | 3.83 |
| 1 ≥ x ≥ 0.5 | 4.03 | 1.32 |
| 0.5 ≥ x ≥ 0.25 | 0.51 | 0.44 |
| ≤0.25 | 0.30 | 0.24 |

Results in Table 2 show that the materials tend to have different PSD. This may be due to the way that the glass was fractured-considering that the modules were delaminated without previous controlled glass fracture steps.

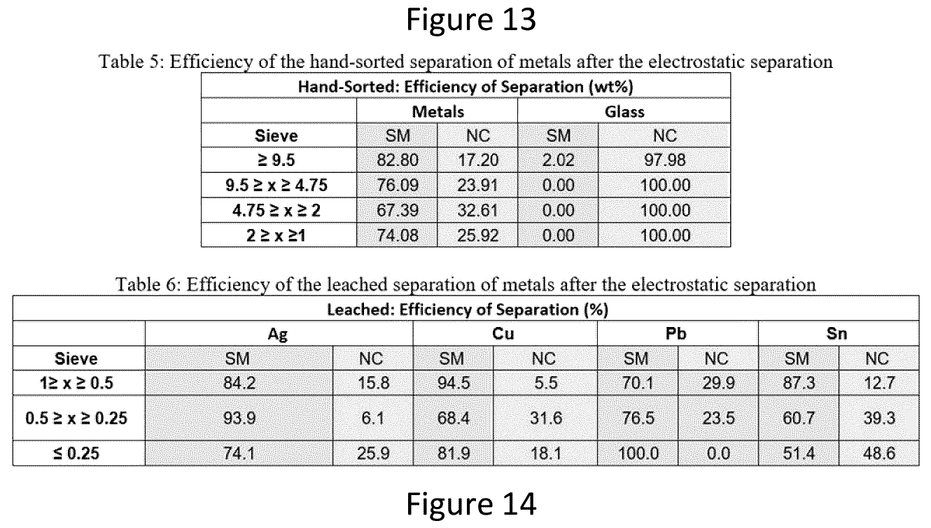

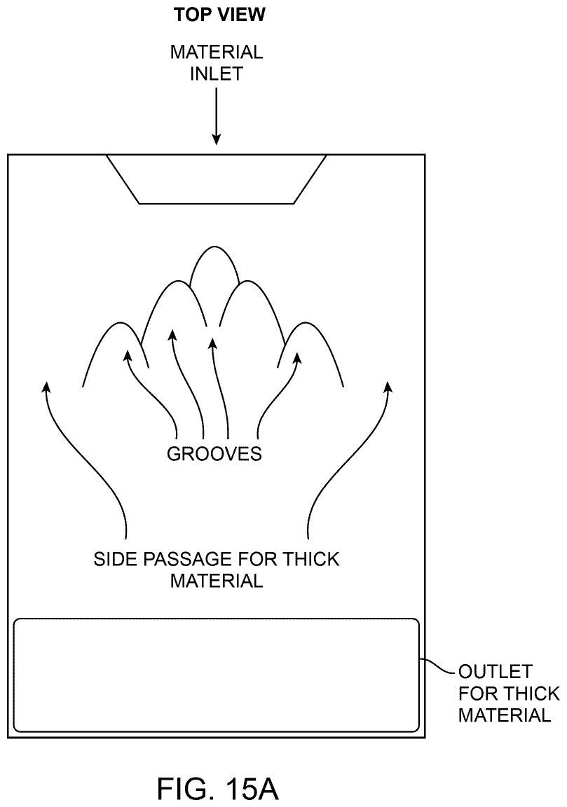

An electrostatic separation for each fraction was performed and both composition and efficiency of separation of each fraction were analyzed. Part of the fractions were hand-sorted in terms of glass and metals (silicon wafer and ribbons) and the other part were leached and analyzed via ICP-OES. The results are presented on Table 3 and 4 (FIGS. 11 and 12, respectively).

Results in Table 3 show that it is possible to obtain fractions in the range of 9.5≥x≥1. However, part of the metals is still present in the non-conductive fraction in the range of 0.2 and 15.59 wt %. It is possible to obtain fractions with the ES, but part of the metals is still found in the non-conductive fractions. The non-conductive fraction may be used in the fabrication of new glass or purified in the thickness separation system.

Results in Table 4 show that it is possible to obtain higher concentrations of Silver and Copper. However, part of the silver and copper is still present in the non-conductive fraction.

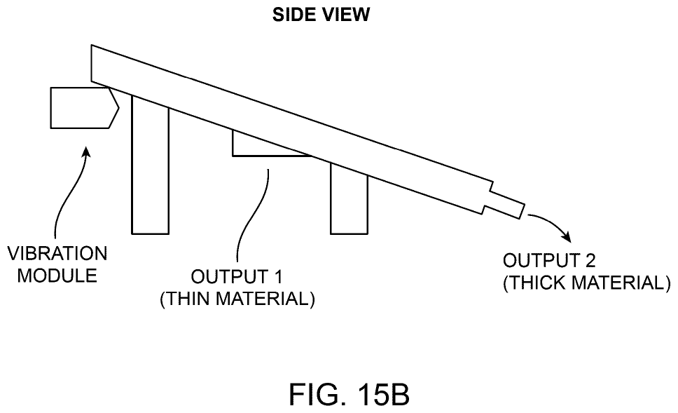

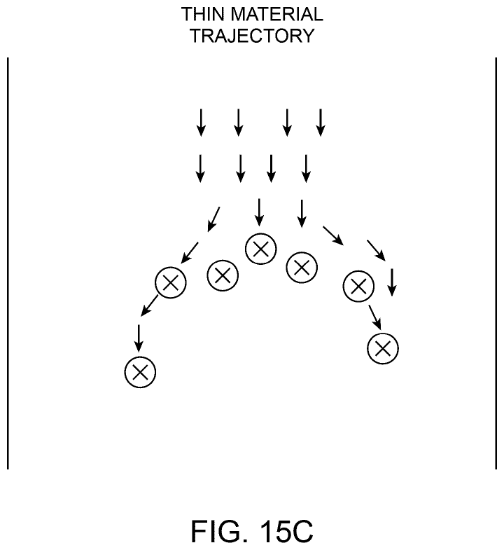

In Tables 5 and 6 (FIGS. 13 and 14 respectively), it is shown the efficiency of the electrostatic separation per fraction. For example, in Table 5, 82.80% of metals in the ≥9.5 fraction are destined to the conductive fraction while 17.20% of metals are destined to the non-conductive fraction.

Results show that the metals tend to concentrate in the conductive fraction, but there are losses. For the coarser fractions, the losses are in the range of ˜25% for the hand-sorted and ˜15% for the leached fractions.

So, considering the PSD differences and the lower efficiency of the ES with the coarser particles, the fine parts of the granulometry would be destined to the electrostatic separation, while the coarser fractions to the thickness separation table.

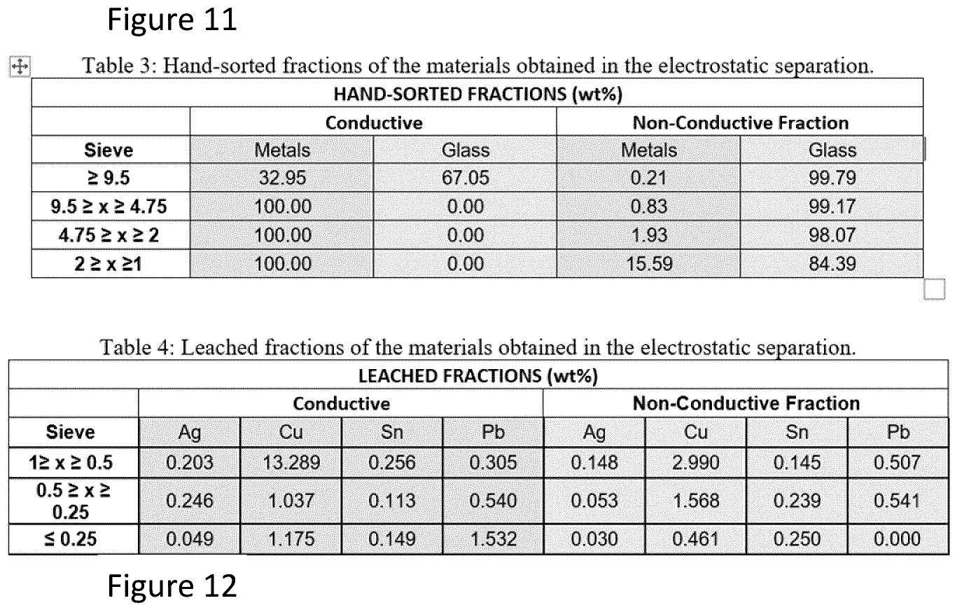

The thickness separation table can produce fractions enriched in silicon as seen previously. The output materials from the thickness separation table (glass+ribbons) can be separated in eddy current separators and separate ribbons from the glass. FIG. 10 shows a simplified flowchart for an embodiment of a recycling method.

As previously mentioned, some embodiments may utilize a furnace to apply the radiation. Embodiments utilizing a furnace to apply radiation, heats up the entire laminate, involving a larger thermal mass than just the polymer encapsulant constituent (˜9:1 ratio). By contrast, the emitter radiation targets specifically the encapsulant and thus allows for energy to be used efficiently.

Heating of polymer encapsulant for delamination can take two paths, both of which are useful. One path heats up the encapsulant to soften it and allow for other techniques to be used in combination with the heating (e.g., arms and/or suction cups).

Another path is to heat up the encapsulant with the objective of physically removing it, e.g., via liquid flow, sublimation, and/or degradation/decomposition. Some leftover carbon may remain.

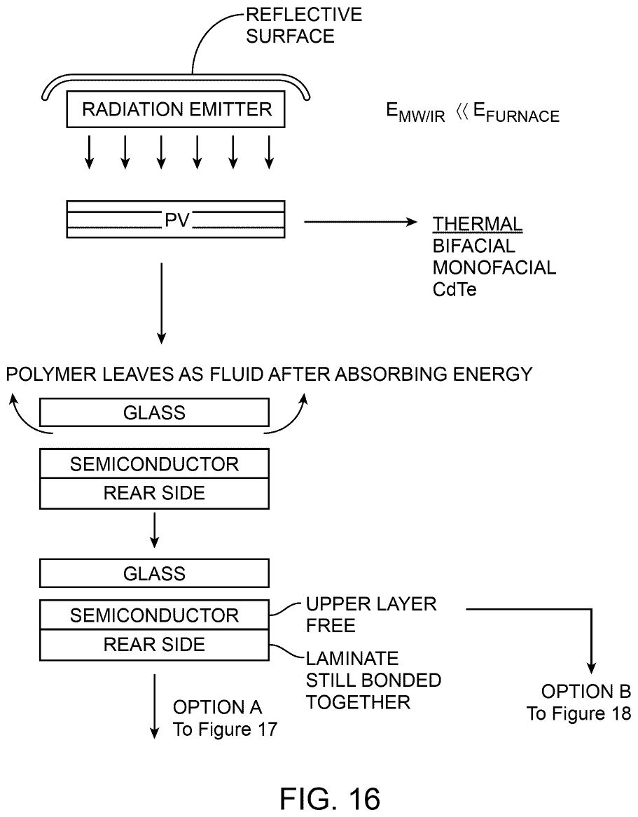

FIGS. 16-18 show a simplified flow diagram for a method of delamination. FIG. 16 shows the application from an emitter, of radiation having an energy less than a furnace. As a result of this, the polymer leaves as a fluid, and a glass is freed and separated.

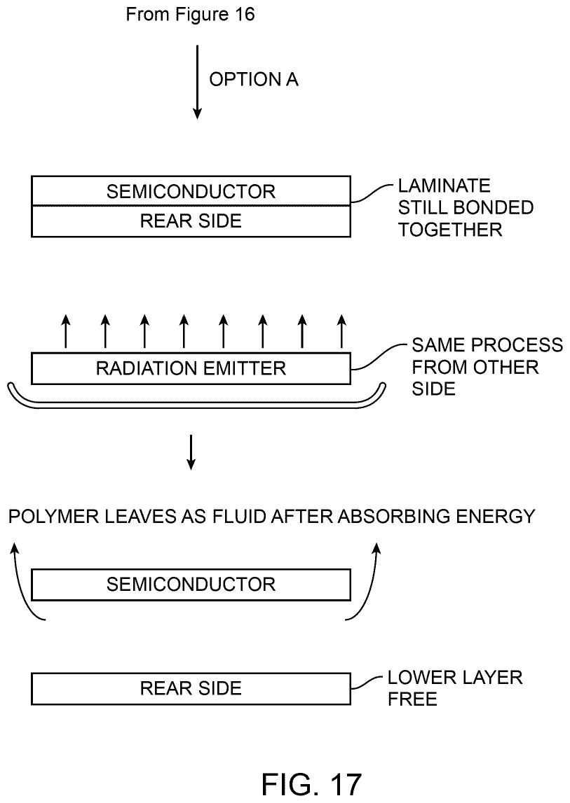

FIG. 17 shows a first option, where radiation from an emitter is then applied to the opposite side. The rear side is heated and the polymer leaves as a fluid, thereby freeing the remaining layers.

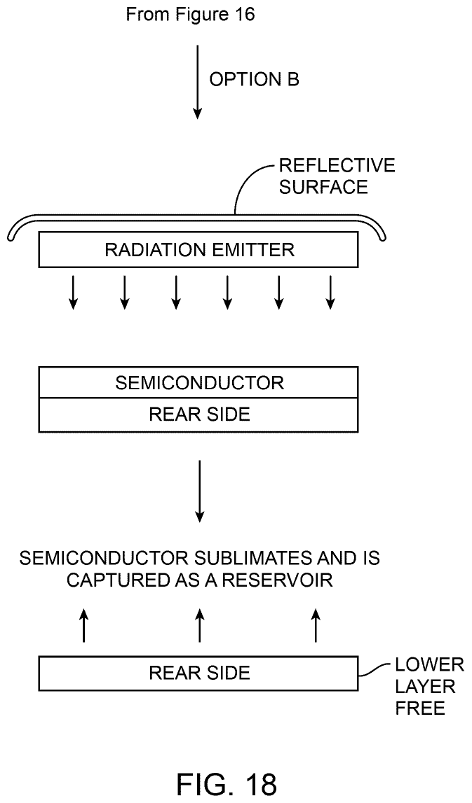

FIG. 18 shows another option, where radiation is continued to be applied from the original side. Here, the semiconductor sublimes (and may later be captured), thereby freeing the lower layer on the rear side.

As mentioned above, removal of oxygen can allow for a process called pyrolysis, rather than combustion, to occur. However it is not necessary to achieve full pyrolysis (i.e., complete absence of oxygen) for all embodiments. Rather, certain embodiments may reduce the available oxygen, offering flexibility to the delamination process and reducing its cost.

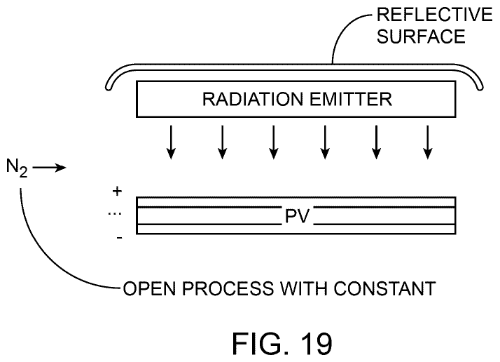

FIGS. 19-21 show simplified embodiments for achieving pyrolysis. The embodiment of FIG. 19 is open, with a constant supply of nitrogen or other inert gas being supplied to reduce the amount of available oxygen.

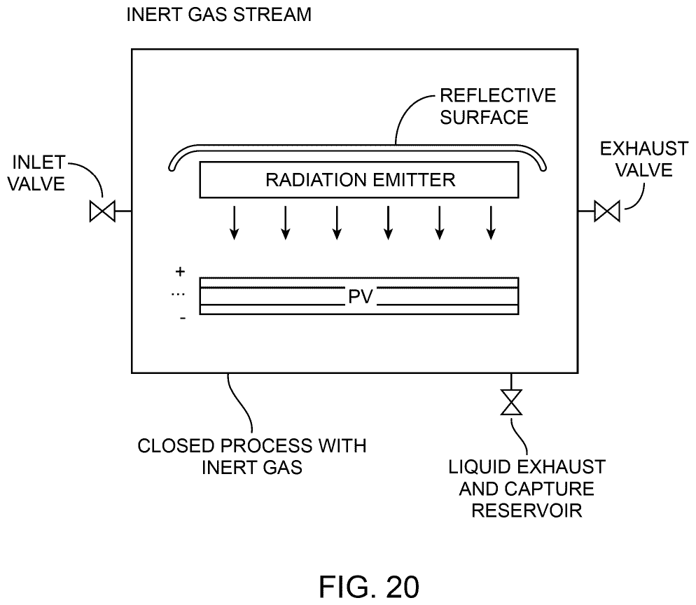

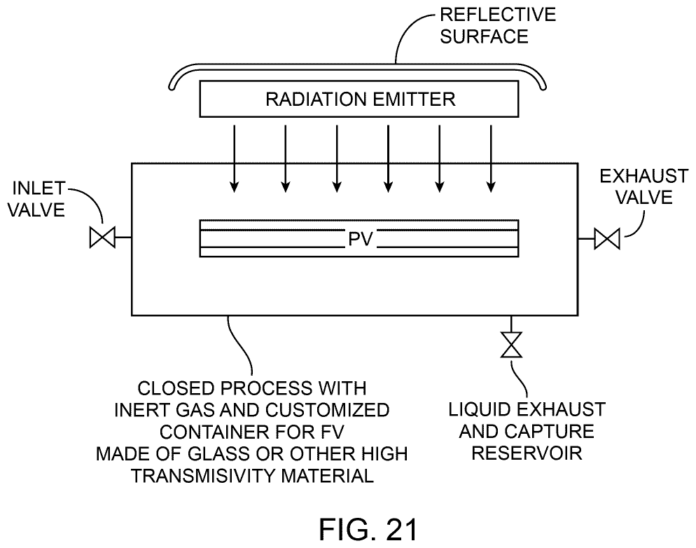

The embodiments of FIGS. 20 and 21 are closed, with the laminate being exposed to an inert gas such as nitrogen and/or a vacuum. In the particular embodiment of FIG. 20, the radiation emitter (and possible reflective surface) are present together with the laminate within a sealed chamber containing the ambient.

In the particular embodiment of FIG. 21, the radiation emitter/reflective surface are external to the laminate within a sealed chamber containing the ambient. The material of the sealed chamber admits the radiation from the emitter into the chamber in order to perform delamination.

Clause 1A. A method comprising:
applying radiation to soften a polymer within a photovoltaic laminate;
gripping a glass layer of the photovoltaic laminate; and
removing at least a portion of the glass layer from the polymer.

Clause 2A. A method as in Clause 1A wherein the radiation is applied prior to the gripping.

Clause 3A. A method as in any of Clauses 1A and 2A wherein the gripping comprises gripping the glass layer with a suction cup.

Clause 4A. A method as in any of Clauses 1A, 2A, and 3A wherein the gripping comprises gripping the glass layer with an arm.

Clause 5A. A method as in any of Clauses 1A, 2A, and 4A wherein the arm is adhered to the glass layer.

Clause 6A. A method as in any of Clauses 1A, 2A, 3A, 4A, and 5A wherein polymer is removed by application of the radiation.

Clause 7A. A method as in Clause any of Clauses 1A, 2A, 3A, 4A, 5A, and 6A wherein polymer is removed by pyrolysis in a reduced oxygen ambient.

Clause 1B. A method comprising:
receiving a mixture resulting from processing of a used photovoltaic module;
communicating the mixture including a silicon particle, to a vibrating table comprising a feature having a dimension; and
separating the silicon particle from the mixture based upon the dimension.

Clause 2B. A method as in Clause 1B wherein the processing comprises application of microwave radiation to the used photovoltaic module.

Clause 3B. A method as in any of Clauses 1B and 2B wherein the feature comprises a ramp.

Clause 4B. A method as in any of Clauses 1B, 2B, and 3B wherein the feature comprises an opening.

Clause 5B. A method as in any of Clauses 1B, 2B, 3B, and 4B wherein the feature comprises a groove.

Clause 6B. A method as in any of Clauses 1B, 2B, 3B, 4B, and 5B wherein the used photovoltaic module is bifacial.

Clause 7B. A method as in any of Clauses 1B, 2B, 3B, 4B, 5B, and 6B wherein the processing comprises application of infrared radiation to the used photovoltaic module.

Clause 8B. A method as in any of Clauses 1B, 2B, 3B, 4B, 5B, 6B, and 7B wherein the processing comprises application of radiation in a furnace to the used photovoltaic module.

Clause 1C. An apparatus comprising:
a chamber configured to receive a laminate of a used solar module;
a valve configured to expose the laminate within the chamber to a reduced oxygen ambient; and
an emitter configured to expose the laminate within the reduced oxygen ambient, to radiation.

Clause 2C. An apparatus as in Clause 1C wherein the emitter is disposed within the chamber.

Clause 3C. An apparatus as in Clause 1C wherein the emitter is disposed outside the chamber and the radiation is communicated through a wall of the chamber.

Clause 4C. An apparatus as in any of Clauses 1C, 2C, and 3C further comprising a reflective surface to direct the radiation from the emitter to the laminate.

Clause 5C. An apparatus as in any of Clauses 1C, 2C, 3C, and 4C wherein the radiation is unidirectional.

Clause 1D. A method comprising:
applying radiation globally to soften a polymer within a photovoltaic laminate of a used solar module; and
removing at least a portion of a glass layer from the polymer.

Clause 2D. A method as in Clause 1D wherein the radiation is applied in a furnace.

Clause 3D. A method as in any of Clauses 1D and 2D wherein polymer is removed by application of the radiation.

Clause 4D. A method as in any of Clauses 1D, 2D, and 3D wherein polymer is removed by pyrolysis in a reduced oxygen ambient.

Clause 5D. A method as in any of Clauses 1D, 2D, 3D, and 4D wherein polymer is removed by combustion.

Clause 6D. A method as in any of Clauses 1D, 2D, 3D, 4D, and 5D wherein the used solar module is bifacial.

Clause 7D. A method as in any of Clauses 1D, 2D, 3D, 4D, 5D, and

6D wherein the used photovoltaic laminate comprises CdTe.

Clause 8D. A method as in any of Clauses 1D, 2D, 3D, 4D, 5D, 6D, and 7D wherein a wavelength of the radiation targets the polymer more than other materials in the photovoltaic laminate.

Clause 9D. A method as in any of Clauses 1D, 2D, 3D, 4D, 5D, 6D, 7D, and 8D wherein the radiation is applied to a backside.

Clause 10D. A method as in any of Clauses 1D, 2D, 3D, 4D, 5D, 6D, 7D, 8D, and 9D wherein the radiation is applied to the glass layer.

Clause 11D. A method as in any of Clauses 1D, 2D, 3D, 4D, 5D, 6D, 7D, 8D, 9D, and 10D wherein the polymer comprises ethylene vinyl acetate (EVA) and/or polyolefin elastomer (POE).

Clause 12D. A method as in any of Clauses 1D, 2D, 3D, 4D, 5D, 6D, 7D, 8D, 9D, 10D, and 11D wherein applying the radiation liberates a chemical from the polymer.

Clause 13D. A method as in Clause 12D wherein the chemical is liberated due to a halogen.

Clause 14D. A method as in any of Clauses 1D, 2D, 3D, 4D, 5D, 6D, 7D, 8D, 9D, 10D, 11D, 12D, and 13D wherein the radiation heats a thermal mass of the photovoltaic laminate.

Clause 15D. A method as in any of Clauses 1D, 2D, 3D, 4D, 5D, 6D, 7D, 8D, 9D, 10D, 11D, 12D, 13D, and 14D wherein the polymer comprises encapsulant.

Clause 16D. A method as in any of Clauses 1D, 2D, 3D, 4D, 5D, 6D, 7D, 8D, 9D, 10D, 11D, 12D, 13D, 15D, and 16D wherein the polymer comprises a backsheet.

Clause 17D. A method as in any of Clauses 1D, 2D, 3D, 4D, 5D, 6D, 7D, 8D, 9D, 10D, 11D, 12D, 13D, 14D, 15D and 16D wherein the photovoltaic laminate comprises:
encapsulant formed from the polymer; and
a backsheet,
wherein the encapsulant is heated without also substantially heating the backsheet.

Clause 18D. A method as in Clause 17D wherein the backsheet comprises glass.

Clause 19D. A method as in any of Clauses 17D and 18D wherein the backsheet comprises another polymer different from the encapsulant.

Clause 20D. A method as in any of Clauses 17D, 18D, and 19D wherein the backsheet comprises the polymer

It is emphasized that the approaches described above may be utilized alone, or in various combinations, in order to effect recycling of photovoltaic modules.

What is claimed is:

1. A method comprising:
providing a used solar module comprising a glass layer, encapsulant, and a photovoltaic material; and
applying radiation to remove at least a portion of the encapsulant and delaminate the used solar module.

2. A method as in claim 1 wherein the encapsulant is removed from the glass layer.

3. A method as in claim 1 wherein the radiation is applied in a controlled thermal process.

4. A method as in claim 3 wherein the radiation is applied in a furnace.

5. A method as in claim 1 wherein encapsulant is removed by pyrolysis in a reduced oxygen ambient.

6. A method as in claim 1 wherein encapsulant is removed by combustion.

7. A method as in claim 1 wherein the used solar module is bifacial.

8. A method as in claim 1 wherein the photovoltaic material comprises CdTe.

9. A method as in claim 1 wherein the photovoltaic material comprises silicon.

10. A method as in claim 1 wherein the encapsulant comprises ethylene vinyl acetate (EVA) and/or polyolefin elastomer (POE).

11. A method as in claim 1 wherein applying the radiation liberates a chemical from the elastomer due to a halogen.

12. A method as in claim 1 wherein encapsulant is removed in a liquid flow.

13. A method as in claim 1 wherein encapsulant is removed by sublimation.

14. A method as in claim 1 wherein encapsulant is removed by degradation or decomposition.

15. A method as in claim 1 wherein some leftover carbon of the encapsulant remains following application of the radiation.

16. A method as in claim 1 wherein a wavelength of the radiation targets the encapsulant more than other portions of the used solar module.

17. A method as in claim 1 wherein the radiation heats a thermal mass of the used solar module.

18. A method as in claim 1 wherein the radiation is unidirectional.

19. A method as in claim 1 wherein the radiation is multidirectional.

20. A method as in claim 1 wherein:
the used solar module is monofacial and includes a polymer backsheet; and
applying the radiation removes at least a portion of the polymer.
